(19) United States
(12) Patent Application Publication
(10) Pub. No.: US 2008/0017898 A1
(43) Pub. Date: Jan. 24, 2008

(54) INTEGRATED CIRCUIT HAVING SECOND EPITAXIAL LAYER

(75) Inventor: Oliver Haeberlen, Villach (AT)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: INFINEON TECHNOLOGIES AUSTRIA AG, Villach (AT)

(21) Appl. No.: 11/780,253

(22) Filed: Jul. 19, 2007

(30) Foreign Application Priority Data
Jul. 19, 2006 (DE) 10 2006 033 505.8

(51) Int. Cl. H01L 29/78

(52) U.S. Cl. 257/288; 257/E29.255

(57) ABSTRACT

An integrated circuit having a semiconductor device with reduced “tail” resistance and production method for such a device is disclosed. One embodiment provides at least one substrate of a first conduction type doped with a first concentration of donors of a first atom type, and a first epitaxial layer of the first conduction type doped with a second concentration of first donor atoms. A second epitaxial layer of the first conduction type doped with a third concentration of donors of a second atom type is formed between the first epitaxial layer and the substrate.

### CROSS-REFERENCE TO RELATED APPLICATIONS

This Utility Patent Application claims priority to German Patent Application No. DE 10 2006 033 505.8 filed on Jul. 19, 2007, which is incorporated herein by reference.

### BACKGROUND

The invention relates to a semiconductor device, in one embodiment a MOSFET.

Field effect transistors (FET) are a group of unipolar transistors, in which, in contrast to the bipolar transistors, only one type of charge carrier is involved in current transport, that is to say either electrons or holes or defect electrons, depending on the design. Between a charge carrier source region (source) and a charge carrier drain region (drain), the flow of the charge carriers is in this case controlled by a control voltage present at a gate.

In contrast to the bipolar transistors, FETs are switched in wattless or lossless fashion to the greatest possible extent. The most widespread type of field effect transistor is the MOSFET (Metal Oxide Semiconductor FET), in which a metal layer forming the connection of the abovementioned gate is insulated by an underlying oxide layer from that section of the semiconductor substrate surface in which the charge carrier flow to be controlled takes place.

MOSFETs are used e.g., for switching and driving resistive, capacitive and inductive loads at relatively high switching frequencies. The FET's advantage that only a control voltage, but not a significantly large control current, is necessary both in the switched-on state and in the switched-off state on account of the field effect is utilized in this case.

What is characteristic of a MOSFET is the maximum permitted breakdown voltage, the overshooting of which leads to the loss of controllability by the gate electrode and, under certain circumstances, to the destruction of the semiconductor device. A high dielectric strength is achieved e.g., by using an additional series resistance, having the highest possible value, of a drift region or epitaxial layer (also designated as “Epi” for short). On the other hand, however, in the switched-on state the on resistance of the switch should be as low as possible in order to avoid power losses.

The on resistance is composed of a plurality of resistance components between the source contact and the drain contact. The type of individual resistance components and the magnitude thereof depend, of course, on the concrete construction of a FET. In general, however, it can be established that a significant reduction of specific resistance components, in particular of the predominant channel resistance and primarily of the spreading resistance, in FETs of the vertical type has been achieved in the course of the further development of production technologies. The total on resistance could therefore be considerably reduced.

In these developments, the resistance component of the substrate material could not be reduced to the same extent, so that its relative proportion of the total on resistance has even risen. Current development efforts aim to reduce it.

It is possible to reduce the resistance component of the substrate by shortening the path distance through which current flows, by reducing the substrate thickness in the case of the vertical construction. This route is actually being pursued—by thinning the substrate—, but is complicated and beset with disadvantages, for instance during handling.

A further possibility consists in reducing the substrate resistivity, in conjunction with an unchanged substrate thickness or else in combination with thinning the substrate. This route, too, is already being pursued in recent developments, to be precise by changing the doping material for producing the n-type conductivity of the substrate. In this case, a transition has been made specifically from arsenic doping to phosphorus doping in recent developments.

This enables higher substrate dopings and hence lower substrate resistances, but has the disadvantage that the higher diffusivity of phosphorus, during the high-temperature processes of the production process, leads to pronounced outdiffusion into an overlaid epitaxial layer.

FIG. 1A and FIG. 1B illustrate, with regard to the example mentioned above, the phosphorus concentration differences between the epitaxial layer Epi and the substrate directly after epitaxy (FIG. 1A) and after the wafer process or heat treatment step (FIG. 1B). The so-called substrate “tail”, which represents a diffusion of the phosphorus atoms into the epitaxial layer, is clearly discernible in FIG. 1B.

Said substrate “tail” likewise supplies, in the sense of an additional resistance component, a significant contribution to the total on resistance of the FET, which may indeed be 10% or more.

For these and other reasons, there is a need for the present invention.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIGS. 1A and 1B illustrate concentration diagrams of the doping of the epitaxial layer and of the substrate in the case of a known MOSFET directly after epitaxial coating and after the wafer process (heat treatment).

FIG. 2 illustrates a schematic illustration of one embodiment of an integrated circuit, including a semiconductor device.

FIGS. 3A and 3B illustrate concentration diagrams of the doping of the first epitaxial layer, of the second epitaxial layer and of the substrate in the case of the embodiment according to FIG. 2 directly after epitaxy and after the wafer process (heat treatment).

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

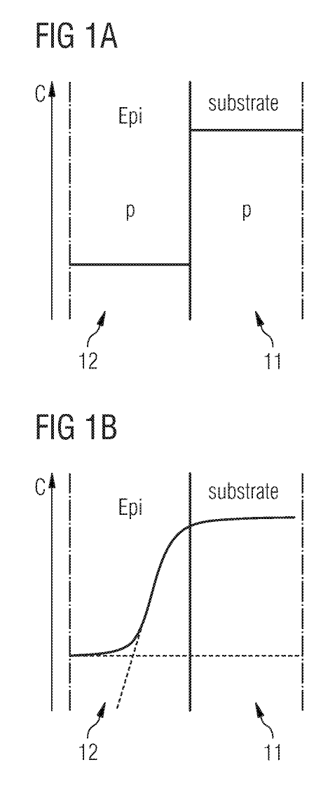

FIG. 1A and FIG. 1B show, with regard to the example mentioned above, the phosphorus concentration differences between the epitaxial layer Epi and the substrate directly after epitaxy (FIG. 1A) and after the wafer process or heat treatment process (FIG. 1B). The substrate “tail”, which represents a diffusion of the phosphorus atoms into the epitaxial layer, is clearly discernible in FIG. 1B.

The substrate “tail” likewise supplies, in the sense of an additional resistance component, a significant contribution to the total on resistance of the FET, which may indeed be 10% or more.

One or more embodiments provide an integrated circuit, including an improved semiconductor device, in one embodiment a low-voltage MOSFET, which has, in particular, a further reduced on resistance. Furthermore, one or more embodiments provide a method suitable for producing such a semiconductor device.

One embodiment provides for developing a FET arrangement formed in/on a phosphorus-doped wafer in such a way that the substrate “tail” and the “tail” resistance is reduced.

In one embodiment, the present invention provides a semiconductor device including at least one substrate of a first conduction type doped with a first concentration of first donor atoms, a first epitaxial layer of the first conduction type provided on the main surface of the substrate and doped with a second concentration of second donor atoms, and a source/gate structure formed at the main surface of the first epitaxial layer. A drain electrode is provided on the opposite rear side of the substrate, wherein a second epitaxial layer of the first conduction type doped with a third concentration of third donor atoms is formed between the first epitaxial layer and the substrate.

In one or more embodiments, the “tail” resistance of the substrate “tail” is reduced by introducing the second epitaxial layer doped with donors of a second atom type, without having to relinquish the advantage of a lower electrical resistance through the substrate doped with donors of the first atom type.

In one embodiment, the thickness and doping of the second epitaxial layer are formed in such a way that a donor diffusion from the substrate into the first epitaxial layer and the “tail” resistance of the substrate “tail” are virtually zero. What is achieved through suitable choice of the donor atom type and thickness of the second epitaxial layer is that the “tail” arising as a result of outdiffusion from the substrate into the adjacent region lies practically completely in the second epitaxial layer and, at the same time, a doping gradient brought about by this additional epitaxial layer in the substrate boundary layer has an extremely steep profile and has no appreciable “tail”.

What is thereby achieved is that it is possible to use e.g., phosphorus-doped substrates for reducing the on resistance. This has the advantage that, in addition, the thickness of the first epitaxial layer can be reduced and, consequently, cost neutrality of the process can be achieved.

Furthermore, the third donor atoms used for forming the second epitaxial layer are preferably arsenic atoms. The advantage is that the lower outdiffusion of arsenic in comparison with phosphorus atoms leads to a very steep rise in the doping from the first epitaxial layer toward the substrate and this transition region has a significantly smaller resistance compared with the transition region of a conventional MOSFET.

The third donor atoms used for forming the second epitaxial layer are antimony atoms, with the same advantages.

Furthermore, the third concentration of the third donor atoms is in one embodiment lower than the first concentration of the first donor atoms. A low diffusion of the donors from the second epitaxial layer is thereby achieved, in which case the second epitaxial layer can be made thin, compared with the first epitaxial layer.

A method employed for producing one embodiment has a process of providing a substrate of a first conduction type doped with a first concentration of first donor atoms, a process of forming a first epitaxial layer of the first conduction type doped with a second concentration of second donor atoms, and a process of forming a FET structure at the main surface of the first epitaxial layer, wherein, before the process of forming the first epitaxial layer, a second epitaxial layer doped with a third concentration of third donor atoms is formed on the substrate.

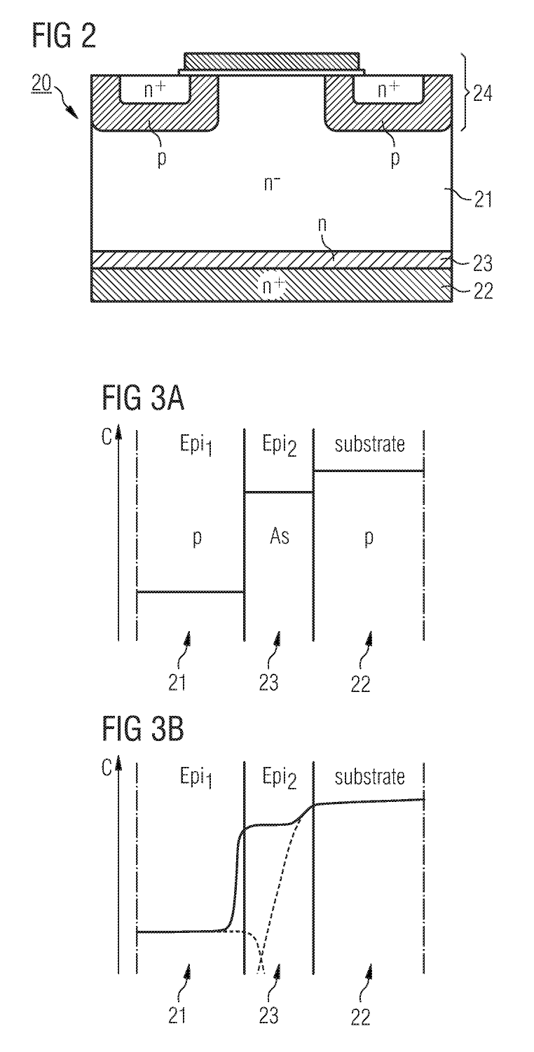

FIG. 2 illustrates an integrated circuit having a semiconductor device. In one embodiment illustrated, the semiconductor device includes a MOSFET, indicated at 20. A MOSFET 20includes a second, arsenic-doped epitaxial layer 23 formed between the first epitaxial layer 21 and the phosphorus-doped substrate 22. A FET-typical well/electrode structure 24 is formed at the main surface of the first epitaxial layer 21. A rear side metallization is not illustrated in the figure. It should be pointed out that MOSFETs with a trench structure constitute one embodiment, however.

By way of example, the substrate 22 includes a highly doped phosphorus substrate wafer 22 having a concentration of 6E19 cm⁻³ and having a resistivity of 1.2 mΩcm. On the latter, in a conventional manner, an arsenic-doped epitaxial layer 20 having a concentration of 6E18 cm⁻³, a thickness of e.g., 6 to 7 μm and a resistivity of 8.5 mΩcm is deposited, followed by the phosphorus-doped epitaxial layer 21 having a concentration of 4E16 cm⁻³, a thickness of e.g., 3 μm and a resistivity of 160 mΩcm.

In another example, the low-voltage MOSFET likewise includes a highly P-doped Si substrate wafer 22 having a concentration of 6E19 cm⁻³ and having a resistivity of 1.2 mΩcm. However, an epitaxial layer that is comparable in terms of the doping conditions, but thinner, having a concentration of 4E16 cm⁻³, a thickness of e.g., 6 to 7 μm and a resistivity of 160 mΩcm is deposited on the P-doped wafer 22. This is followed by coating with arsenic glass and a high-temperature process for the “drive-in”. After the etching away of the oxide and cleaning, there follows the phosphorus-doped first epitaxial layer 21 having a concentration of 4E16 cm⁻³, a thickness of e.g., 3 μm and a resistivity of 160 mΩcm.

The concentration diagrams illustrated in FIGS. 3A/3B illustrate the different concentration of the donors between the phosphorus-doped first epitaxial layer 21, the arsenic-doped second epitaxial layer 23 and the phosphorus substrate 22 directly after epitaxy and after the wafer process (heat treatment).

The substrate “tail” of the P-doped substrate 22 that arose in the second epitaxial layer 23 as a result of outdiffusion of the phosphorus atoms is represented in this case by a dashed black line, the substrate “tail” not reaching the first epitaxial layer 21. Consequently, the “tail” resistance in the transition region between substrate 22 and first epitaxial layer 21 is significantly reduced. It is therefore possible to reduce the thickness of the first epitaxial layer 21 since the phosphorus outdiffusion into the latter no longer has to be taken into account.

The embodiment of the invention is not restricted to these examples described above and the highlighted aspects and parameters mentioned, but rather is likewise possible in a multiplicity of modifications that lie within the scope of expert action.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit having a semiconductor device comprising:
at least one substrate of a first conduction type doped with a first concentration of first donor atoms;
a first epitaxial layer of the first conduction type doped with a second concentration of second donor atoms; and
a second epitaxial layer of the first conduction type doped with a third concentration of third donor atoms formed between the first epitaxial layer and the substrate.

2. The integrated circuit of claim 1, wherein the semiconductor device is configured as a FET.

3. The integrated circuit of claim 1, where a donor diffusion between the substrate and the first epitaxial layer is substantially zero.

4. The integrated circuit of claim 1, where donor outdiffusion from the substrate into the first epitaxial layer is significantly reduced relative to a semiconductor device having only a one epitaxial layer.

5. The integrated circuit of claim 1, comprising:
a source/gate structure formed at the main surface of the first epitaxial layer.

6. The semiconductor device of claim 1, comprising wherein the first donor atoms are phosphorus atoms.

7. The semiconductor device of claim 1, comprising wherein the second donor atoms are phosphorus, arsenic or antimony atoms.

8. The semiconductor device of claim 1, comprising wherein the third donor atoms are arsenic or antimony atoms.

9. The semiconductor device of claim 1, comprising wherein the third concentration of the third donor atoms is lower than the first concentration of the first donor atoms.

10. The semiconductor device of claim 1, comprising wherein a thickness of the second epitaxial layer lies within the range of between 3 μm and 10 μm.

11. The semiconductor device of claim 1, comprising wherein the third concentration of the third donor atoms is a factor of 2 to 20 lower than the first concentration of the first donor atoms.

12. A semiconductor device comprising:
at least one substrate of a first conduction type doped with a first concentration of first donor atoms;
a first epitaxial layer of the first conduction type doped with a second concentration of second donor atoms, and a source/gate structure formed at the main surface of the first epitaxial layer, wherein
a second epitaxial layer of the first conduction type doped with a third concentration of third donor atoms is formed between the first epitaxial layer and the substrate, the second epitaxial layer being formed in such a way that a donor outdiffusion from the substrate into the first epitaxial layer is significantly reduced.

13. The semiconductor device of claim 12, comprising wherein the first donor atoms are phosphorus atoms.

14. The semiconductor device of claim 12, comprising wherein the second donor atoms are phosphorus, arsenic or antimony atoms.

15. The semiconductor device of claim 12, comprising wherein the third donor atoms are arsenic or antimony atoms.

16. The semiconductor device of claim 12, comprising wherein the third concentration of the third donor atoms is lower than the first concentration of the first donor atoms.

17. The semiconductor device of claim 12, comprising wherein a thickness of the second epitaxial layer lies within the range of between 3 μm and 10 μm.

18. The semiconductor device of claim 12, comprising wherein the third concentration of the third donor atoms is a factor of 2 to 20 lower than the first concentration of the first donor atoms.

19. A method for producing a semiconductor device of claim 12, comprising:
providing a substrate of a first conduction type doped with a first concentration of first donor atoms;
forming a first epitaxial layer of the first conduction type doped with a second concentration of second donor atoms;
wherein, before the process of forming the first epitaxial layer, a second epitaxial layer doped with a third concentration of third donor atoms is formed on the substrate in such a way that a donor outdiffusion from the substrate into the first epitaxial layer is significantly reduced.

20. The method of claim 19, comprising using phosphorus atoms as first donor atoms and using arsenic or antimony atoms as third donor atoms.

21. The method of claim 19, comprising setting the third concentration of the second donor atoms to be lower than the first concentration of the first donor atoms.

22. An integrated circuit having a semiconductor device comprising:
at least one substrate of a first conduction type doped with a first concentration of first donor atoms;
means for providing a first epitaxial layer of the first conduction type doped with a second concentration of second donor atoms; and
means for providing a second epitaxial layer of the first conduction type doped with a third concentration of third donor atoms formed between the first epitaxial layer and the substrate.
